(19) United States
(12) Patent Application Publication
(10) Pub. No.: US 2020/0350425 A1
(43) Pub. Date: Nov. 5, 2020

(54) INTEGRATION OF HETEROGENEOUS TRANSISTORS ON DIAMOND SUBSTRATE

(71) Applicant: QUALCOMM Incorporated, San Diego, CA (US)

(72) Inventors: Ranadeep DUTTA, Del Mar, CA (US); Jonghae KIM, San Diego, CA (US); Je-Hsiung LAN, San Diego, CA (US)

(21) Appl. No.: 16/401,240

(22) Filed: May 2, 2019

(51) Int. Cl. H01L 29/778; H01L 29/66; H01L 27/088; H01L 29/16; H01L 29/20

(52) U.S. Cl. CPC H01L 29/7783; H01L 29/66462; H01L 29/1602; H01L 29/16; H01L 29/2003; H01L 27/088

(57) ABSTRACT

A semiconductor device having heterogeneous transistors integrated on a diamond substrate. An example semiconductor device generally includes a diamond substrate, a first transistor disposed above the diamond substrate, the first transistor comprising gallium nitride, and a second transistor disposed above the diamond substrate, the second transistor comprising a different semiconductor than the first transistor.

### BACKGROUND

### Field of the Disclosure

Certain aspects of the present disclosure generally relate to electronic circuits and, more particularly, to a semiconductor device having heterogeneous transistors integrated on a diamond substrate.

### Description of Related Art

A continued emphasis in semiconductor technology is to create improved performance semiconductor devices at competitive prices. This emphasis over the years has resulted in extreme miniaturization of semiconductor devices, made possible by continued advances in semiconductor processes and materials in combination with new and sophisticated device designs. Many of the semiconductor devices that are contemporaneously being created are aimed at processing digital data. There are, however, also numerous semiconductor designs that are aimed at incorporating analog functions into devices that simultaneously process digital and analog signals, or devices that can be used for the processing of only analog signals.

An example of a semiconductor device that may incorporate analog and digital functions is a radio frequency front-end. A wireless communication device, such as a base station or user equipment, may include a radio frequency front-end for transmitting and/or receiving radio frequency signals. The radio frequency front-end may include transistors to implement various analog and digital devices, such as control circuitry, switches, duplexers, diplexers, multiplexers, power amplifiers, low noise amplifiers, mixers, etc. The devices implemented with transistors may be fabricated on a semiconductor wafer. Some of the transistor devices (such as a power amplifier) may be fabricated as discrete components and interconnected to the other devices of the radio frequency front-end.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include an improved radio frequency front-end for a wireless communication device.

Certain aspects of the present disclosure provide a semiconductor device. The semiconductor device generally includes a diamond substrate, a first transistor disposed above the diamond substrate, the first transistor comprising gallium nitride, and a second transistor disposed above the diamond substrate, the second transistor comprising a different semiconductor than the first transistor.

Certain aspects of the present disclosure provide a method of fabricating a semiconductor device. The method generally includes forming a first transistor at least partially in a semiconductor region disposed above a diamond substrate; forming a cavity in a dielectric region; and forming a second transistor, comprising gallium nitride, in the cavity and above the diamond substrate, wherein the first transistor comprises a different semiconductor than the second transistor.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a block diagram showing an example radio frequency front-end, in accordance with certain aspects of the present disclosure.

FIG. 2 is a cross-sectional view of an example semiconductor device having heterogeneous transistors disposed above a diamond substrate, in accordance with certain aspects of the present disclosure.

FIG. 3A is a cross-sectional view of an example semiconductor-diamond substrate, in accordance with certain aspects of the present disclosure.

FIG. 3B is a cross-sectional view of a first transistor disposed above the diamond substrate, in accordance with certain aspects of the present disclosure.

FIG. 3C is a cross-sectional view of a cavity formed in a dielectric layer disposed above the diamond substrate, in accordance with certain aspects of the present disclosure.

FIG. 3D is a cross-sectional view of a second transistor comprising gallium nitride disposed above the diamond substrate, in accordance with certain aspects of the present disclosure.

FIG. 3E is a cross-sectional view of the second transistor having contacts formed thereon, in accordance with certain aspects of the present disclosure.

FIG. 4 is a flow diagram of example operations for fabricating a semiconductor device, in accordance with certain aspects of the present disclosure.

### DETAILED DESCRIPTION

Aspects of the present disclosure generally relate to a semiconductor device (such as a radio frequency front-end integrated circuit (RFFE IC)) having heterogeneous transistors integrated on a diamond substrate. Co-integration of heterogeneous transistors (such as high voltage transistors and digital logic level transistors) on a diamond substrate provides performance and reliability benefits to the RFFE IC due to the enhanced thermal conductivity, higher resistivity, and lower loss-tangent of the diamond substrate, compared to other conventional substrates (e.g., silicon or sapphire). For example, the diamond substrate may improve heat dissipation and reduce crosstalk between digital and analog components (e.g., control logic and an RF power amplifier). Also, co-integration of the transistors and passive components (such as capacitors, inductors, and resistors) may reduce parasitic losses encountered when these components are interconnected as discrete components on the RFFE IC, especially when a discrete power amplifier is coupled to the RFFE IC. Further, co-integration of the heterogeneous transistors and passive components may provide cost benefits related to the fabrication process, such as enabling the fabrication of the heterogeneous transistors and passive components at a single fabrication facility.

### Example RE Front-End

An RF front-end typically includes electronic components such as control logic, switches, digital circuits, low noise amplifiers (LNAs), power amplifiers (PAs), etc. These electronic components may be assembled as discrete elements on a laminate substrate such as a glass-reinforced epoxy laminate (e.g., FR4) substrate. The discrete components on the RF front-end may lead to high parasitic resistances, inductances, and/or capacitances, resulting in significant parasitic losses, especially at 5G New Radio wireless access bands (such as sub-6 GHz (e.g., 450-6000 MHz) bands and/or mmWave bands (e.g., 24-30 GHz)).

The RF front-end may also suffer poor thermal dissipation and crosstalk between electronic components due to the substrate material, especially at the 5G New Radio wireless access bands. For example, gallium arsenide (GaAs) and silicon (Si) substrates may suffer from poor thermal conductivity resulting in significant self-heating on high-density components. Also, the gallium arsenide and silicon substrates may also provide a poor substrate resistivity and loss tangent, which affects the crosstalk and interference encountered by the electronic components.

The discrete components may also affect the fabrication costs and cycle time of the RF front-end. The discrete components may be fabricated individually in separate fabrication facilities, on different size wafers, at significant cost and various cycle times. For example, gallium nitride (GaN), which provides suitable performance characteristics for power amplification, can be very expensive due to smaller diameter, more expensive GaN or silicon carbide (SiC) substrates and production in dedicated fabrication facilities (such as group III-V compound semiconductor facilities).

Certain aspects of the present disclosure generally relate to an example semiconductor device (such as an RF front-end integrated circuit) having heterogeneous transistors integrated on a diamond substrate. For example, the example semiconductor device may have gallium nitride (GaN) high electron mobility transistors (HEMT) configured for high voltage, high speed applications (e.g., a power amplifier (PA) on a transmit path of the RF front-end) and complementary metal-oxide-semiconductor (CMOS) transistors used in various applications (e.g., control logic, switches, digital circuits, and/or low noise amplifiers). The example semiconductor device may integrate the GaN transistors and CMOS transistors on a single diamond substrate.

The diamond substrate improves the performance, ruggedness, and reliability of the RF front-end due to vastly higher thermal conductivity, higher resistivity, and lower loss-tangent of the diamond substrate compared to conventional substrates. The co-integration of the GaN transistors, CMOS transistors, and passive components (such as coupling capacitors, filters, etc.) on a single wafer may also provide cost and cycle time benefits as the transistor fabrication may be performed at a single semiconductor fabrication facility. The co-integration of the GaN transistors, CMOS transistors, and passive components may also significantly reduce parasitic losses due to component interconnects, which is highly beneficial for operating at high frequencies, such as 5G NR wireless access bands.

As used herein, high voltage applications may include operating electronic components (such as the example GaN HEMT described herein) at voltages significantly higher than digital power supply rails, for example, for maximizing power delivered by an RF PA to an antenna (output power may be proportional to the square of the voltage). A high speed device generally refers to a device that has sufficiently high transition frequency (f_{T}) and maximum frequency (fₘₐₓ) (e.g., typically 3 to 10 times the operating frequency) to ensure good performance (e.g., output power, gain, efficiency) at the operating frequency, such as at the 5G NR wireless access bands.

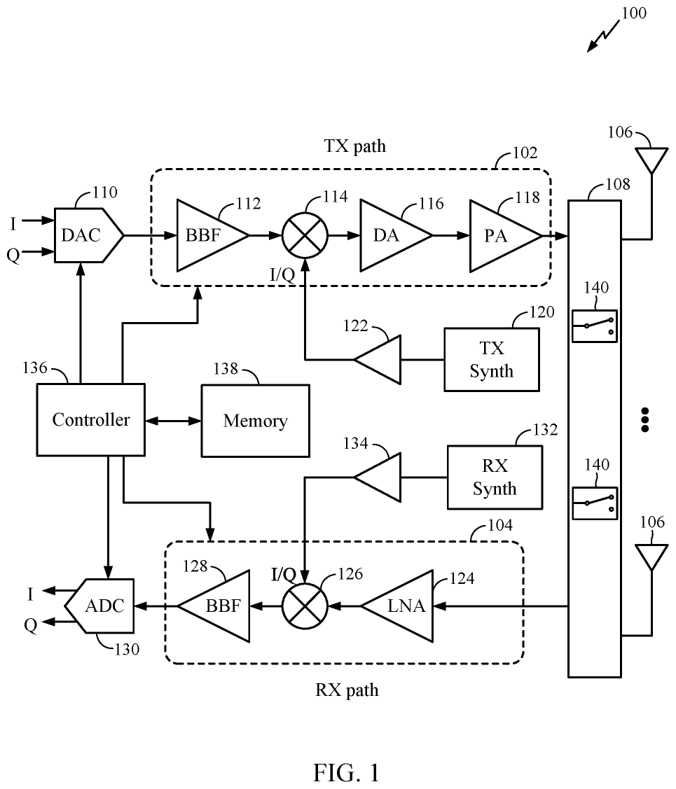

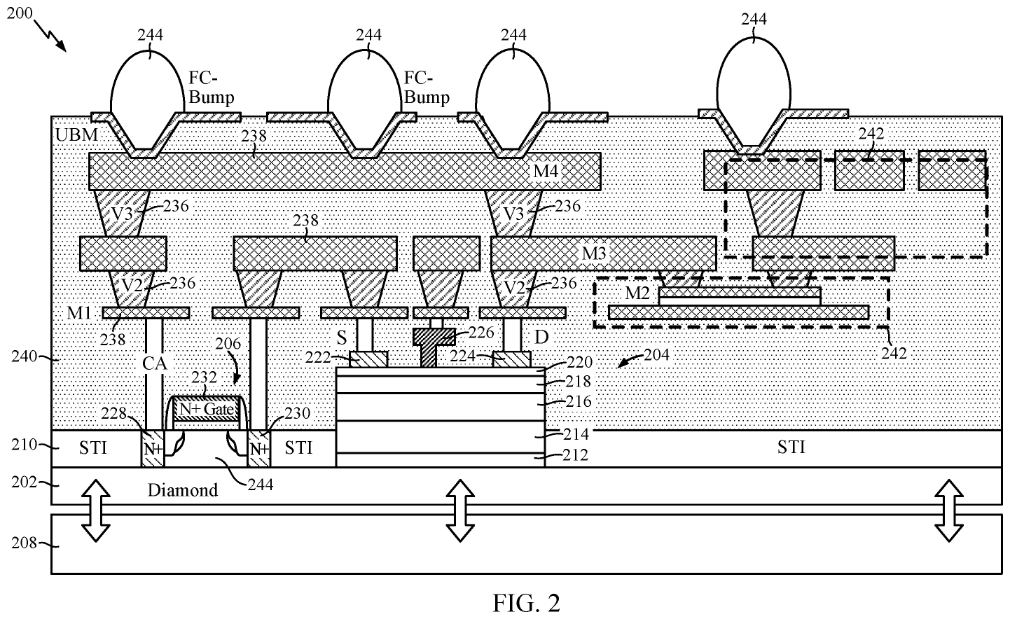

FIG. 1 is a block diagram of an example RF front-end 100, in accordance with certain aspects of the present disclosure. The RF front-end 100 may include heterogeneous transistors integrated on a diamond substrate as further described herein with respect to FIG. 2.

The RF front-end 100 includes at least one transmit (TX) path 102 (also known as a transmit chain) for transmitting signals via one or more antennas 106 and at least one receive (RX) path 104 (also known as a receive chain) for receiving signals via the antennas 106. When the TX path 102 and the RX path 104 share an antenna 106, the paths may be connected with the antenna via an interface 108, which may include any of various suitable RF devices, such as a switch 140, a duplexer, a diplexer, a multiplexer, and the like. The switch 140 may include a CMOS transistor as further described herein with respect to FIG. 2. In certain aspects, one or more switches 140 may be included in other components, such as a tunable capacitor array for a tunable filter or a frequency synthesizer, used in the RF front end 100.

Receiving in-phase (I) or quadrature (Q) baseband analog signals from a digital-to-analog converter (DAC) 110, the TX path 102 may include a baseband filter (BBF) 112, a mixer 114, a driver amplifier (DA) 116, and a power amplifier (PA) 118. The BBF 112, the mixer 114, the DA 116, and the PA 118 may be included in a semiconductor device such as a radio frequency integrated circuit (RFIC). As examples, the BBF 112 and/or mixer 114 may include CMOS transistors, whereas the PA 118 may include GaN HEMTs, as further described herein with respect to FIG. 2.

The BBF 112 filters the baseband signals received from the DAC 110, and the mixer 114 mixes the filtered baseband signals with a transmit local oscillator (LO) signal to convert the baseband signal of interest to a different frequency (e.g., upconvert from baseband to a radio frequency). This frequency conversion process produces the sum and difference frequencies between the LO frequency and the frequencies of the baseband signal of interest. The sum and difference frequencies are referred to as the beat frequencies. The beat frequencies are typically in the RF range, such that the signals output by the mixer 114 are typically RF signals, which may be amplified by the DA 116 and/or by the PA 118 before transmission by the antenna 106.

The RX path 104 may include a low noise amplifier (LNA) 124, a mixer 126, and a baseband filter (BBF) 128. The LNA 124, the mixer 126, and the BBF 128 may be included in a RFIC, which may or may not be the same RFIC that includes the TX path components. RF signals received via the antenna 106 may be amplified by the LNA 124, and the mixer 126 mixes the amplified RF signals with a receive local oscillator (LO) signal to convert the RF signal of interest to a different baseband frequency (e.g., downconvert). The baseband signals output by the mixer 126 may be filtered by the BBF 128 before being converted by an analog-to-digital converter (ADC) 130 to digital I or Q signals for digital signal processing. For example, the LNA 124 may be implemented with CMOS or GaN based transistors, as further described herein with respect to FIG. 2.

While it is desirable for the output of an LO to remain stable in frequency, tuning to different frequencies indicates using a variable-frequency oscillator, which involves compromises between stability and tunability. Contemporary systems may employ frequency synthesizers with a voltage-controlled oscillator (VCO) to generate a stable, tunable LO with a particular tuning range. Thus, the transmit LO may be produced by a TX frequency synthesizer 120, which may be buffered or amplified by amplifier 122 before being mixed with the baseband signals in the mixer 114. Similarly, the receive LO may be produced by an RX frequency synthesizer 132, which may be buffered or amplified by amplifier 134 before being mixed with the RF signals in the mixer 126.

A controller 136 may direct the operation of the RF front-end 100, such as transmitting signals via the TX path 102 and/or receiving signals via the RX path 104. The controller 136 may be a processor, a digital signal processor (DSP), an application specific integrated circuit (ASIC), a field programmable gate array (FPGA) or other programmable logic device (PLD), discrete gate or transistor logic, discrete hardware components, or any combination thereof. The memory 138 may store data and program codes for operating the RF front-end 100. The controller 136 and/or memory 138 may include control logic (e.g., CMOS logic), which may include CMOS transistors as further described herein with respect to FIG. 2.

While FIG. 1 provides an RF front-end as an example application in which certain aspects of the present disclosure may be implemented to facilitate understanding, certain aspects described herein related to a semiconductor device having heterogeneous transistors integrated on a diamond substrate may be utilized in any of various other suitable electronic systems.

### Example Integration of Heterogeneous Transistors on a Diamond Substrate

FIG. 2 is a cross-sectional view of an example semiconductor device 200 that has heterogeneous transistors disposed above a diamond substrate, in accordance with certain aspects of the present disclosure. As shown, the semiconductor device 200 may include a diamond substrate 202, a first transistor 204, and a second transistor 206. The first transistor 204 may be disposed adjacent to the second transistor 206 on the diamond substrate 202.

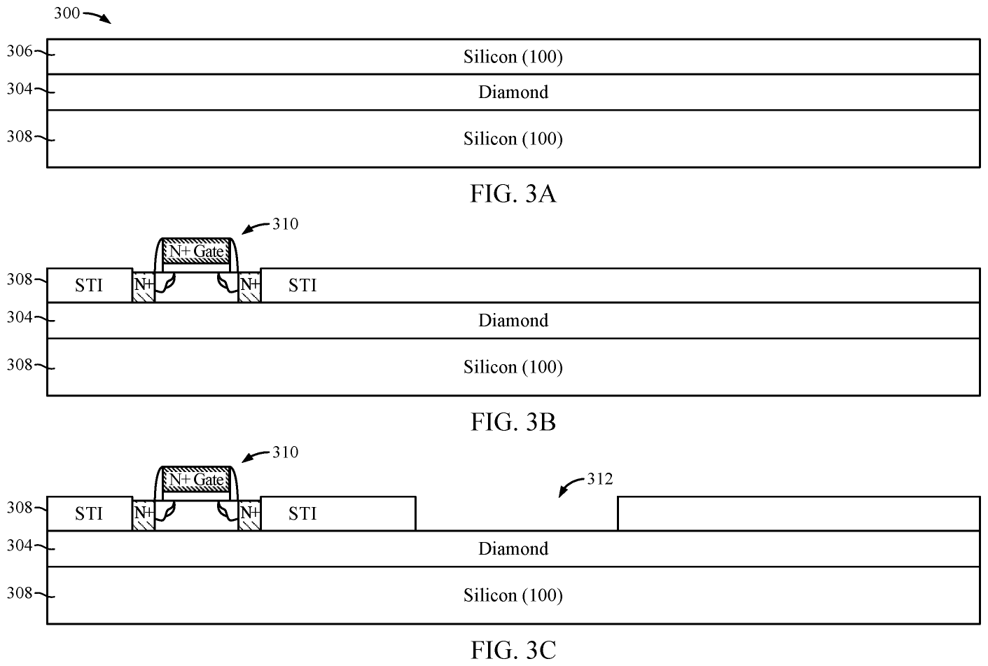

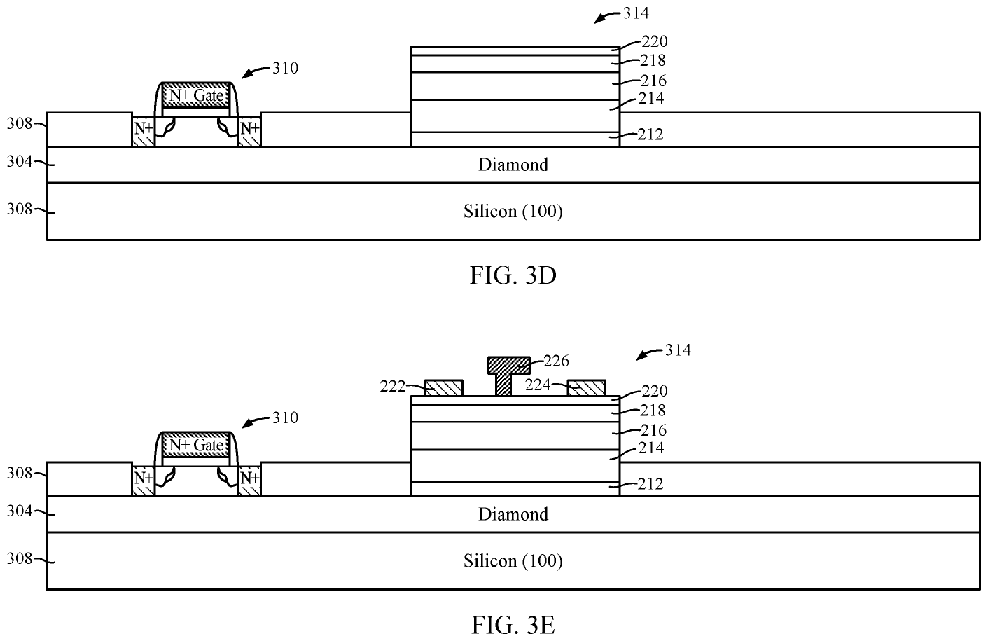

For certain aspects, the diamond substrate 202 may be a synthetic diamond produced by a chemical vapor deposition (CVD) process. The diamond substrate 202 may provide vastly higher thermal conductivity, higher resistivity, and lower loss-tangent compared to other substrate materials, such as silicon dioxide, silicon, or gallium arsenide. The diamond substrate 202 may be disposed between a semiconductor handle 208 (e.g., a bulk silicon support wafer or handle) and a dielectric region 210. For example, the diamond substrate 202 may be a diamond layer included in a silicon-on-diamond wafer comprising a silicon layer, diamond substrate layer, and a bulk silicon handle as further described herein with respect to FIG. 3A. The second transistor 206 may be partially fabricated in the silicon layer, which may then be selectively etched and filled with a dielectric to form the dielectric region 210. In certain aspects, the semiconductor handle 208 may be thinned or removed after fabricating the various components of the semiconductor device 200 using the semiconductor handle 208.

As an example, the dielectric region 210 may comprise an oxide, such as silicon dioxide. As illustrated in FIG. 2, the dielectric region 210 may be a shallow trench isolation (STI) region configured to electrically isolate the transistors 204, 206 from other components. The dielectric region 210 may be disposed above the diamond substrate 202 and between the first and second transistors 204, 206.

The first transistor 204 may comprise gallium nitride (GaN) and be a high electron mobility transistor (HEMT). The first transistor 204 may be configured for high speed, high voltage applications such as power amplification. For example, a power amplifier (e.g., PA 118 of FIG. 1) may include the first transistor 204 to amplify RF signals at high frequencies, such as in the 5G NR wireless access bands.

The first transistor 204 may include a nucleation layer 212, a buffer layer 214, a channel layer 216, a barrier layer 218, and a cap layer 220. The first transistor 204 may also include a source terminal 222, a drain terminal 224, and a gate terminal 226, each of which is disposed above the channel layer 216.

The nucleation layer 212 may be disposed above the diamond substrate 202. The nucleation layer 212 may be any suitable nucleation layer (e.g., an aluminum nitride (AlN) layer) that facilitates growth of a GaN structure, such as the first transistor 204, due to the lattice mismatch between the diamond substrate 202 and GaN transistor.

The buffer layer 214 may be disposed above the nucleation layer 212. As an example, the buffer layer 214 may include a graded aluminum gallium nitride (AlGaN) buffer. The buffer layer 214 may reduce strains on the GaN structure due to mismatches in thermal expansion coefficients and lattice constants between the GaN transistor and other materials, such as the diamond substrate 202, dielectric region 210, and dielectric layers 240.

The channel layer 216 may be disposed above the buffer layer 214. The channel layer 216 may include gallium nitride, for example.

The barrier layer 218 may be disposed above the channel layer 216. The barrier layer 218 may include at least one of aluminum gallium nitride, indium aluminum nitride (e.g., In_{0.17}Al_{0.83}N), or any suitable lattice-matched barrier with GaN. An aluminum gallium nitride barrier may include from 20 to 30% aluminum, for example. The cap layer 220 may be disposed above the barrier layer 218. The cap layer 220 may include gallium nitride, for instance. The barrier layer 218 and cap layer 220 may be configured to enhance the performance of the first transistor 204 for high speed, high voltage applications, such as by increasing the transition frequency and maximum frequency.

Like the first transistor 204, the second transistor 206 may also be disposed above the diamond substrate 202, but may include a different semiconductor than the first transistor 204. For example, the second transistor 206 may include silicon instead of gallium nitride. Portions of the second transistor 206 may be formed in a semiconductor region, as described herein with respect to FIGS. 3A and 3B, the semiconductor region being disposed above the diamond substrate 202. The semiconductor region may comprise any of various suitable semiconductor materials, such as silicon. The second transistor 206 may have a source region 228 and a drain region 230 implanted in the semiconductor region. The second transistor 206 may also include a gate region 232 and a channel region 234. The gate region 232 may be disposed above the channel region 234 formed in the semiconductor region. For example, the gate region 232 may comprise a polysilicon gate.

The second transistor 206 may be configured as an n-type metal-oxide-semiconductor (NMOS) transistor. For example, the source region 228 and the drain region 230 may be n+ doped semiconductors. While the examples provided herein are described with respect to an NMOS transistor to facilitate understanding, aspects of the present disclosure may also be applied to a p-type MOS (PMOS) transistor. For example, for a PMOS transistor, the source region 228 and drain region 230 may be p+ doped semiconductors.

The first and second transistors 204, 206 may be coupled together and/or to various conductive elements including through-hole plated vias 236 and conductive layers 238 (e.g., metal layers of a back end of line (BEOL) process) in one or more dielectric layers 240. The conductive elements may electrically couple the first and second transistors 204, 206 to other electrical devices including, but not limited to, other transistors and/or passive components 242 (e.g., a capacitor, inductor, and/or resistor). For example, the conductive elements may facilitate the co-integration of the first transistor 204, second transistor 206, and passive components 242 on the diamond substrate 202, thereby reducing parasitics encountered when, for example, some of the various components (such as a power amplifier, control logic, or filters) are discrete components.

The passive components 242 may be disposed above the diamond substrate 202 in the dielectric layers 240. The passive components 242 may be electrically coupled (e.g., through the vias 236 and/or the conductive layers 238) to at least one of the first transistor 204 or the second transistor 206. The passive components 242 may include a capacitor (e.g., a metal-insulator-metal (MIM) capacitor), inductor, or a resistor. In certain aspects, a filter (e.g., the BBF 112 or BBF 128) may include the passive components 242.

The semiconductor device 200 may be a flip-chip ball grid array (FC-BGA) integrated circuit having multiple solder bumps 244. In certain aspects, the semiconductor device 200 may include a RF front-end integrated circuit (e.g., the RF front-end 100 or TX path 102). The RF front-end integrated circuit (RFFE IC) may include a power amplifier (e.g., PA 118) that includes the first transistor 204. The RFFE IC may include a switch (e.g., switch 140), control logic (e.g., the controller 136 and/or memory 138), or an LNA (e.g., LNA 124), any of which may include the second transistor 206.

FIGS. 3A-3E illustrate example operations for fabricating a semiconductor device having heterogeneous transistors integrated on a diamond substrate, in accordance with certain aspects of the present disclosure. The operations may be performed by a semiconductor processing chamber, for example.

As shown in FIG. 3A, a silicon-on-diamond (SOD) wafer 300 may be formed. The SOD wafer 300 may include a silicon handle 302 (e.g., the semiconductor handle 208), a diamond substrate 304 (e.g., the diamond substrate 202), and a semiconductor region 306. The semiconductor region 306 may be disposed above the diamond substrate 304, which may be disposed above the silicon handle 302.

Referring to FIG. 3B, the semiconductor region 306 may be selectively etched, and the etched portions may be filled with a dielectric (e.g., silicon dioxide (Sift)) to form at least one dielectric region 308 (e.g., the dielectric region 210). For example, the semiconductor region 306 may be etched with a pattern of trenches, which then may be filled with a dielectric material to form the dielectric region(s) 308.

A first transistor 310 (e.g., the second transistor 206) may be partially formed in the semiconductor region 306, such that the source and drain regions are implanted in the semiconductor region 306 and a gate region is disposed above a channel region also formed in the semiconductor region 306 as described herein with respect to FIG. 2. The first transistor 310 may be produced, for example, using a self-aligned CMOS transistor fabrication process up to silicidation. That is, the first transistor 310 may be produced using the CMOS transistor fabrication process without performing an anneal process to form silicide contacts for the drain, source, and/or gate. In certain aspects, a dielectric layer (e.g., one of the dielectric layers 240) and a silicon nitride (Si₃N₄) layer may be deposited above the first transistor 310 and the dielectric region 308.

As illustrated in FIG. 3C, a cavity 312 may be formed in the dielectric region 308. For example, a mask may be applied that isolates the GaN HEMT regions during an etching process, which removes a portion of the dielectric region 308 and forms the cavity 312.

Referring to FIG. 3D, a second transistor 314 (e.g., the first transistor 204) may be formed above the diamond substrate 304. The second transistor 314 may include the nucleation layer 212, buffer layer 214, channel layer 216, barrier layer 218, and cap layer 220, as described herein with respect to FIG. 2. The layers of the second transistor 314 may be grown above the diamond substrate 304 and in the cavity 312 using a selective epitaxy growth process. For example, a mask may be applied to isolate the GaN HEMT region as the GaN transistor layers are epitaxial grown. The epitaxy growth process used to produce the second transistor 314 may include a molecular beam epitaxy (MBE) process or a metalorganic chemical vapor deposition (MOCVD) epitaxy process. The MBE process may be preferred due to the low temperatures encountered during the epitaxy process, and thus, reducing any diffusion or thermal strains during the epitaxy process. In certain aspects, the epitaxial growth of the second transistor 314 may be performed before the CMOS transistor fabrication process used to produce the first transistor 310 as described herein with respect to FIG. 3B. By fabricating the second transistor 314 before the first transistor 310, the thermal budget impact to the CMOS is mitigated. Therefore, for the fabrication sequence where the second transistor 314 is fabricated before the first transistor 310, either of MOCVD (preferred for manufacturability and cost) or MBE may be used for the epitaxy, toward creating the second transistor 314.

As depicted in FIG. 3E, the source terminal 222, drain terminal 224, and gate terminal 226 of the second transistor 314 may be formed above the channel layer 216. The gate terminal 226 may be formed as a T-gate (Schottky) by patterning silicon nitride (e.g., Si₃N₄) above the cap layer 220.

After forming the first and second transistors 310, 314 (i.e., front end of line process) on the diamond substrate 304, the back end of line process may be performed. For example, the silicidation of the source, drain, and gate regions of the first transistor 310 may be performed. One or more dielectric layers (e.g., dielectric layers 240) may be formed above the first and second transistors 310, 314. Then, the individual devices (transistors, capacitors, resistors, inductors, etc.) may be electrically coupled with conductive elements, such as the through-hole plated vias 236 and conductive layers 238 shown in FIG. 2, to form the various electrical devices of the semiconductor device (BBF, mixer, PA, LNA, filter, control logic, etc.). A passivation layer (e.g., Si₃N₄) may be deposited to protect the semiconductor device.

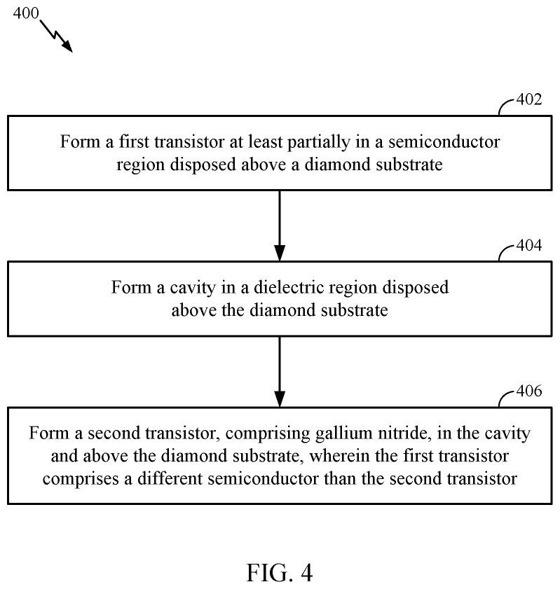

FIG. 4 is a flow diagram of example operations 400 for fabricating a semiconductor device (e.g., the semiconductor device 200 of FIG. 2), in accordance with certain aspects of the present disclosure. The operations 400 may be performed by a semiconductor fabrication facility, for example. In certain aspects, the semiconductor device may be a RF front-end integrated circuit (e.g., RF front end 100 or the TX path 102).

The operations 400 begin, at block 402, by forming a first transistor (e.g., the first transistor 310) at least partially in a semiconductor region (e.g., the semiconductor region 306) disposed above a diamond substrate (e.g., the diamond substrate 304). At block 404, a cavity (e.g., the cavity 312) may be formed in a dielectric region (e.g., dielectric region 308) disposed above the diamond substrate, for example, the cavity may be formed adjacent to the first transistor. At block 406, a second transistor (e.g., the second transistor 314) may be formed in the cavity and above the diamond substrate.

In certain aspects, the second transistor of operations 400 may include gallium nitride, and the first transistor may include a different semiconductor than the second transistor.

Forming the second transistor at block 406 may include growing (or otherwise depositing) layers of the second transistor using an epitaxial growth process as described herein with respect to FIG. 3E. The layers may include the nucleation layer 212, buffer layer 214, channel layer 216, barrier layer 218, and cap layer 220, as described herein with respect to FIG. 2. Forming the second transistor at block 406 may include forming the second transistor before forming the first transistor at block 402.

The following description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim. The word “exemplary” is used herein to mean “serving as an example, instance, or illustration.” Any aspect described herein as “exemplary” is not necessarily to be construed as preferred or advantageous over other aspects.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components.

The following description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim. The word “exemplary” is used herein to mean “serving as an example, instance, or illustration.” Any aspect described herein as “exemplary” is not necessarily to be construed as preferred or advantageous over other aspects.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes and variations may be made in the arrangement, operation and details of the methods and apparatus described above without departing from the scope of the claims.

1. A semiconductor device comprising:
a diamond substrate;
a dielectric region disposed above the diamond substrate and having a cavity;
a first transistor disposed above the diamond substrate and disposed in the cavity in the dielectric region, the first transistor comprising gallium nitride; and
a second transistor disposed above the diamond substrate, the second transistor comprising a different semiconductor than the first transistor.

2. The semiconductor device of claim 1, wherein the first transistor comprises a high electron mobility transistor.

3. The semiconductor device of claim 1, wherein the dielectric region is disposed between the first transistor and the second transistor.

4. The semiconductor device of claim 1, wherein the first transistor further comprises:
a nucleation layer disposed above the diamond substrate;
a buffer layer disposed above the nucleation layer; and
a channel layer disposed above the buffer layer.

5. The semiconductor device of claim 4, wherein the first transistor further comprises:
a barrier layer disposed above the channel layer; and
a cap layer disposed above the barrier layer.

6. The semiconductor device of claim 5, wherein:
the buffer layer comprises aluminum gallium nitride;
the channel layer comprises gallium nitride;
the barrier layer comprises at least one of aluminum gallium nitride or indium aluminum nitride; and
the cap layer comprises gallium nitride.

7. The semiconductor device of claim 4, wherein the first transistor further comprises:
a source terminal disposed above the channel layer;
a drain terminal disposed above the channel layer; and
a gate terminal disposed above the channel layer.

8. The semiconductor device of claim 1, wherein the first transistor is disposed adjacent to the second transistor on the diamond substrate.

9. The semiconductor device of claim 1, wherein the second transistor comprises silicon.

10. The semiconductor device of claim 1, further comprising one or more passive components disposed above the diamond substrate and coupled to at least one of the first transistor or the second transistor.

11. The semiconductor device of claim 1, wherein the semiconductor device comprises a radio frequency front-end (RFFE) integrated circuit (IC), wherein the RFFE IC comprises a power amplifier, and wherein the power amplifier comprises the first transistor.

12. The semiconductor device of claim 11, wherein the RFFE IC comprises a switch, and wherein the switch comprises the second transistor.

13. The semiconductor device of claim 11, wherein the RFFE IC comprises control logic and wherein the control logic comprises the second transistor.

14. The semiconductor device of claim 13, wherein the control logic comprises complementary metal-oxide-semiconductor (CMOS) logic.

15. The semiconductor device of claim 11, wherein the RFFE IC comprises a low noise amplifier (LNA) and wherein the LNA comprises at least one of the first transistor or the second transistor.

16. A method of fabricating a semiconductor device, comprising:
forming a first transistor above a diamond substrate;
forming a cavity in a dielectric region disposed above the diamond substrate; and
forming a second transistor, comprising gallium nitride, in the cavity and above the diamond substrate, wherein the first transistor comprises a different semiconductor than the second transistor.

17. The method of claim 16, wherein forming the second transistor comprises growing layers of the second transistor using an epitaxial growth process, the layers including a nucleation layer, a buffer layer, and a channel layer, a barrier layer, and a cap layer.

18. The method of claim 17, wherein:
the nucleation layer is formed above the diamond substrate;
the buffer layer is formed above the nucleation layer;
the channel layer is formed above the buffer layer;
the barrier layer is formed above the channel layer; and
the cap layer is formed above the barrier layer.

19. The method of claim 16, wherein forming the second transistor comprises forming the second transistor before forming the first transistor.

20. The method of claim 16, wherein the semiconductor device comprises a radio frequency front-end (RFFE) integrated circuit (IC).
